(19) United States
(12) Patent Application Publication
(10) Pub. No.: US 2005/0280036 A1
(43) Pub. Date: Dec. 22, 2005

(54) Semiconductor product having a first and at least one further semiconductor circuit and method

(76) Inventors: Stephan Schroeder, Munchen (DE); Manfred Proell, Dorfen (DE); Arndt Gruber, Munchen (DE); Georg Erhard Eggers, Munchen (DE)

Correspondence Address: SLATER & MATSIL LLP, 17950 PRESTON ROAD, SUITE 1000, DALLAS, TX, 75252, US

(21) Appl. No.: 11/146,305

(22) Filed: Jun. 6, 2005

(30) Foreign Application Priority Data
Jun. 4, 2004 (DE) 10 2004 027 273.5

(51) Int. Cl. H01L 27/10

(52) U.S. Cl. 257/208

(57) ABSTRACT

A semiconductor product includes a first semiconductor circuit and at least one further integrated semiconductor circuit arranged together on a semiconductor substrate. The first semiconductor circuit and the at least one further semiconductor circuit are separated from one another by a frame region and each including contact connections. Interconnects cross the frame region and short-circuit a contact connection of the first semiconductor circuit with a contact connection of the at least one further semiconductor circuit.

This application claims priority to German Patent Application 10 2004 027 273.5, which was filed Jun. 4, 2004 and is incorporated herein by reference.

### TECHNICAL FIELD

The invention relates to a semiconductor product having a first and at least one further semiconductor circuit. The invention furthermore relates to a method for producing a semiconductor product and a method for testing at least one semiconductor circuit.

### BACKGROUND

Semiconductor products are produced by forming integrated semiconductor circuits on a substrate, for instance a semiconductor wafer, a multiplicity of technological process steps being used. For reasons of saving costs, the process steps such as, for example, layer deposition, doping, etching, mask patterning, etc., are always performed at the entire semiconductor wafer in order to produce a maximum number of identical semiconductor circuits simultaneously with the least possible expenditure of labor. After application of the process steps, there arises on the semiconductor wafer a multiplicity of semiconductor circuits that are usually arranged in the form of a checkered grid. In this case, each integrated semiconductor circuit, insofar as it is not arranged too near the edge of the semiconductor wafer, is surrounded by four nearest adjacent identical semiconductor circuits.

On the semiconductor wafer, strip-type regions in which auxiliary structures or test circuits for carrying out a wafer level test may be arranged are in each case provided between adjacent semiconductor circuits. These auxiliary circuits are used for the electrical functional test of the actual semiconductor circuits before the semiconductor wafer is singulated. The strip-type regions between the respective semiconductor circuits run continuously in two directions, for example x and y, on the surface of the semiconductor wafer and form a frame that extends to all the semiconductor circuits and surrounds each semiconductor circuit individually in each case. This frame is also referred to as a sawing frame (kerf or scribe line) since it is preferably removed by a sawing device during the singulation of the wafer. Individual semiconductor chips are thereby formed, which are then connected to a superordinate switching unit, for example a memory module, with the aid of a housing or in unhoused fashion. Each semiconductor product fabricated in this way has precisely one of the integrated semiconductor circuits fabricated on the semiconductor wafer.

Semiconductor wafers on which test circuits for the electrical functional test of the individual semiconductor circuits are arranged are disclosed in U.S. Pat. No. 5,285,082, U.S. Pat. No. 5,214,657, U.S. Pat. No. 5,059,899 and European Patent Application EP 0 427 328, all of which are hereby incorporated herein by reference. The test circuits used therein, since they are arranged on the sawing frame, are destroyed during singulation, as are all the remaining auxiliary structures that are possibly arranged in a sawing frame. The test circuits have interconnects that extend as far as contact connections of surrounding integrated semiconductor circuits and make contact with these in order to electrically test the semiconductor circuits. In this case, each interconnect is connected to a contact connection of only a single semiconductor circuit, to be precise of that semiconductor circuit that is being tested with the aid of the relevant interconnects. In order to obtain a specific test result for each semiconductor circuit, the semiconductor circuits can be driven separately. In particular, contact connections of the semiconductor circuits driven by a test circuit are never short-circuited with one another by the interconnects since this would prevent an individual testing of individual semiconductor circuits.

Despite the advancing miniaturization of integrated semiconductor circuits, the demand for additional memory capacity is growing so rapidly that structurally identical semiconductor memories are provided in many applications, for instance in memory modules. The memory and read-out speed is increased further by increasing the bus width, i.e., the parallelism of the data stream within memory circuits and in the region of their external driving.

Despite these measures, accommodating a sufficiently large number of memory circuits in a confined space poses problems. Stacked memory components (stacked components) are known, in the case of which two semiconductor circuits, for example memory circuits of a DRAM (dynamic random access memory), are accommodated in a common housing. Consequently, a basic area that is only half as large is required for mounting two memory circuits for example on a printed circuit board of a memory module. Two memory circuits in each case are then stacked one above another in a common housing mounted on the printed circuit board. Semiconductor products of this type are complicated to produce since contact connections on two different substrate portions or semiconductor chips are to be electrically connected to the printed circuit board.

As an alternative to using stacked memory components, it is also possible to form the semiconductor circuit of the semiconductor product with a higher bus width and a higher number of memory units. As a result, however, either a new circuit design becomes necessary or the required basic area of the memory product has to be enlarged.

### SUMMARY OF THE INVENTION

In one aspect, the present invention provides a semiconductor product that can carry out circuit operations of a plurality of conventional semiconductor products simultaneously and that can be produced with only little technological additional outlay in comparison with a conventional semiconductor product. The semiconductor product according to embodiments of the invention is furthermore intended to be able to be operated with comparatively few connecting lines and to be able to be mounted in a simple manner at a conventional housing. Furthermore, the intention is to provide a method for producing such a semiconductor product. Finally, the intention is to provide a method for testing at least one semiconductor circuit that can be carried out with a reduced number of contact elements of a test device and in which mechanical loads that arise upon the emplacement of the test device are smaller than in a conventional test method.

In one embodiment, a semiconductor product has a first and at least one further integrated semiconductor circuit, which are arranged together on a semiconductor substrate (semiconductor die or semiconductor body). The first semiconductor circuit and the at least one further semiconductor circuit on the semiconductor substrate are separated from one another by a frame region. The first and the at least one further semiconductor circuit respectively have contact connections. Interconnects are provided that cross the frame region and that, in each case, short-circuit a contact connection of the first semiconductor circuit with a contact connection of the at least one further semiconductor circuit.

According to embodiments of the invention, two or more integrated semiconductor circuits, to be precise a first and at least one other second semiconductor circuit, are provided on a semiconductor substrate of the semiconductor product. The second semiconductor circuit is separated from the first by a frame region arranged between both semiconductor circuits. Both semiconductor circuits have contact connections.

According to embodiments of the invention, interconnects that cross the frame region and short-circuit the contact connections of a plurality of semiconductor circuits with one another are provided on the semiconductor product. If the semiconductor product has precisely two semiconductor circuits, each interconnect couples a contact connection of the first semiconductor circuit to a contact connection of the semiconductor circuit. According to embodiments of the invention, the respective contact connections are short-circuited with one another by the interconnect, i.e., directly connected to one another without additional circuits being interposed in the region of interconnects. By virtue of the interconnects provided according to embodiments of the invention, the semiconductor circuits are connected in parallel and can be operated with comparatively few external connecting lines despite the multiple semiconductor circuits present. No additional outlay for producing complex housings is required since the plurality of semiconductor circuits of the semiconductor product are monolithically connected to one another. Furthermore, the internal circuit construction of the individual semiconductor circuits does not need to be altered in order to realize a higher number of switching operations or a higher memory capacity with a multiple number of memory units. The semiconductor product according to embodiments of the invention, which may have semiconductor circuits with a known, predetermined circuit layout, can be produced without an appreciably technological additional outlay.

It is preferably provided that the semiconductor product has control lines and address lines, which are connected directly to the contact connections of the first semiconductor circuit and which are short-circuited with contact connections of the at least one further semiconductor circuit by the interconnects. Consequently, the same number of leads as is required for a conventional semiconductor product having only one semiconductor circuit suffices for transmitting control commands and memory addresses.

It is preferably provided that the semiconductor product furthermore has data lines and a circuit select line, by means of which a semiconductor circuit to be driven can be activated. The data lines serve for writing in or reading out data. The circuit select line, also referred to as a chip select line, serves for activating or deactivating a semiconductor chip if a plurality of integrated products are connected in parallel in a larger structural unit, for instance a memory module.

It is preferably provided that the data lines are connected directly to contact connections of the first semiconductor circuit and are short-circuited with contact connections of the at least one further semiconductor circuit by the interconnects, whereas a dedicated circuit select line is provided for each semiconductor circuit of the semiconductor product, the dedicated circuit select line being connected only to the respective semiconductor circuit. In this case, all the semiconductor circuits connected in parallel by the interconnects are accessed simultaneously always on the same side by means of the data lines. Whether and what semiconductor circuits are actually internally addressed thereby depends on which of these semiconductor circuits are activated by the circuit select lines. Since the semiconductor circuits can be activated or deactivated individually and independently of the rest of the semiconductor circuits, data can selectively be stored in or read out from a specific semiconductor circuit of the semiconductor product without the rest of the semiconductor circuits of the product being accessed. By means of the circuit select lines, the semiconductor circuits are separated in terms of circuitry in the same way as two semiconductor circuits arranged on two separate conventional semiconductor products.

One development of this embodiment provides for the at least one further semiconductor circuit to be assigned a circuit select line, which is connected directly to a contact connection, which is arranged on the first semiconductor circuit, is electrically insulated from the first semiconductor circuit and is short-circuited with a contact connection of the at least one further semiconductor circuit by an interconnect. In this case, that chip select contact, which is provided for activating or deactivating the further semiconductor circuit, is not arranged on the latter, but on the first semiconductor circuit. This has the advantage that all of the contact connections of the product according to embodiments of the invention are arranged in the region of the first semiconductor circuit, which facilitates making electrical contact externally. Furthermore, when testing such a product, a test head has to be connected to the contact connections only in the region of the first semiconductor circuit.

Another embodiment provides for the circuit select line to be connected directly to a contact connection of the first semiconductor circuit and to be short-circuited with a contact connection of the at least one further semiconductor circuit by an interconnect, whereas dedicated data lines are provided for each semiconductor circuit of the semiconductor product, the dedicated data lines being conductively connected only to the respective semiconductor circuit. In this alternative embodiment, only a single chip select line is provided, which is led to a contact connection of the first semiconductor circuit and is electrically connected to a corresponding contact connection of the at least one further semiconductor circuit with the aid of one of the interconnects. Consequently, all of the semiconductor circuits of the semiconductor product can be activated or deactivated simultaneously by means of the chip select line. However, a dedicated set of data lines, for example of 4, 8, 16 or 32 data lines, is provided for each semiconductor circuit. With the circuit-specific data lines, it is possible in each case for different items of information to be written to the individual semiconductor circuits, so that the semiconductor circuits can be operated independently of one another.

One development of this alternative embodiment provides for the at least one further semiconductor circuit to be assigned data lines that are connected directly to contact connections that are arranged on the first semiconductor circuit, are electrically insulated from the first semiconductor circuit and are short-circuited with contact connections of the at least one further semiconductor circuit by interconnects. As a result, for driving all of the semiconductor circuits, connecting lines have to be fitted only in the region of the first semiconductor circuit.

It is preferably provided that the semiconductor product has a clock signal line, which is connected directly to a contact connection of the first semiconductor circuit and which is short-circuited with a contact connection of the at least one further semiconductor circuit by an interconnect.

It is furthermore preferably provided that the frame region is a region of a sawing frame that has been preserved between the first and the at least one further semiconductor circuit. Consequently, the frame region does not need to be produced by means of additional measures, but rather is obtained simply by dispensing with the destruction of the sawing frame in the region directly between the first semiconductor circuit and an adjacent further semiconductor circuit. The frame region as a base for the interconnects crossing it is made useable according to the invention as a permanent constituent part of a produced end product, whereas it is conventionally destroyed.

It is preferably provided that the first semiconductor circuit and the at least one further semiconductor circuit are arranged at a distance from one another of more than 100 micrometers. This distance corresponds to the width of the frame region in the direction parallel to the interconnects that run over it and are provided according to the invention. The width of the frame region may be in particular 200 to 400 μm, preferably 200 to 300 μm. In any event, the distance between the first and the further semiconductor circuit, according to the invention, is substantially greater than the distance between structures that are arranged next to one another within a single integrated semiconductor circuit; such distances amounting to a hundred or a few hundred nanometers are significantly smaller than the width of a sawing frame (kerf) surrounding that of the integrated circuits.

The contact connections of the semiconductor circuits are preferably bonding contact pads. Such “bond pads” are uncovered on a completed, unhoused semiconductor chip. They are connected by bonding connections to leads of a housing and serve for connecting the circuit-internally integrated control lines, address lines, data lines, etc., to corresponding outer sections of control lines, address lines, data lines, etc., of a housing or a superordinate electronic unit, for instance a memory module.

It is preferably provided that the semiconductor product has a housing and lines connected to the contact connections of the first semiconductor circuit are formed as bonding connections in sections in the housing. Any known type of housing can be used as a housing for the semiconductor product. In particular, TSOP housings (Thin Small Outline Package) or else BGA housings (Ball Grid Array) are suitable; the latter serve for producing a chip size package in which the size of the semiconductor product can be chosen freely. The unhoused semiconductor substrate is in each case enclosed by the housing on all sides. Furthermore, the interconnects, which interconnect the semiconductor circuits in parallel and are provided according to embodiments of the invention, are also protected by the housing.

One preferred embodiment provides for the semiconductor product to have precisely two semiconductor circuits, the contact connections of which are short-circuited with one another in each case in pairs by the interconnects.

As an alternative to this, the semiconductor product may have more than two semiconductor circuits, which are separated from one another by a frame region in each case on the semiconductor substrate and the contact connections of which are in each case short-circuited with one another by interconnects. In this case, each interconnect connects a contact connection of the first semiconductor circuit to a respective contact connection of each further semiconductor circuit.

It is preferably provided that the first semiconductor circuit and all the further semiconductor circuits, the contact connections of which are short-circuited with the contact connections of the first semiconductor circuit by the interconnects, are structurally identical semiconductor circuits. In this case, the semiconductor product is produced by virtue of the fact that the semiconductor circuits intended for the product, during the singulation of a semiconductor wafer are left on a contiguous portion of the semiconductor wafer, that is to say remain monolithically connected to one another. The sawing frame is, therefore, not removed in regions of the sawing frame that lie between the relevant semiconductor circuits.

Finally, it is provided that the semiconductor circuits of the semiconductor product are in each case memory circuits, in particular memory circuits of dynamic random access memories.

In other embodiments, the invention provides a method in which a multiplicity of integrated semiconductor circuits are fabricated on a semiconductor wafer. The semiconductor circuits are arranged on the semiconductor wafer in such a way that a frame remains on the semiconductor wafer. This frame extends to all the semiconductor circuits and surrounds each semiconductor circuit individually. Contact connections are formed on each semiconductor circuit. The contact connections are uncovered on the semiconductor wafer. Interconnects short-circuit the contact connections of a first semiconductor circuit with contact connections of at least one further semiconductor circuit. The semiconductor wafer can then be singulated in such a way that a frame region of the frame that is arranged between the first semiconductor circuit and the further semiconductor circuit is preserved and the first semiconductor circuit and the further semiconductor circuit remain monolithically connected.

In comparison with a conventional method, the above method differs by the fact that interconnects are formed before the singulation of the semiconductor wafer, and that the complete separation of each semiconductor circuit from all the remaining semiconductor circuits is dispensed with during the singulation of the semiconductor wafer. Instead, the semiconductor wafer is singulated for example to form substrate portions (“substrates” or “semiconductor bodies” or “dice”) each having two integrated semiconductor circuits. Individual sawing steps are thereby obviated. Overall, only a slight additional outlay arises as a result of the production of the interconnects. The semiconductor product produced according to embodiments of the invention has a multiple of the storage capacity of conventional semiconductor memories and can be used more diversely.

Preferably, the first and the at least one further semiconductor circuit, which are left on a common substrate portion (“substrate” or “semiconductor body” or “die”) in the method according to embodiments of the invention, are jointly housed by a housing.

Furthermore, it is preferably provided that the frame surrounding the semiconductor circuits on the semiconductor wafer is a sawing frame.

Preferably, the semiconductor wafer is singulated in such a way that a multiplicity of semiconductor products each having two integrated semiconductor circuits that are monolithically connected to one another is produced. In this case, the sawing frame is preserved between the first and the further semiconductor circuit and the interconnects can be used for driving the further semiconductor circuit in the finished semiconductor chip.

In another aspect, the invention provides a method in which a multiplicity of integrated semiconductor circuits are fabricated on a semiconductor wafer. The semiconductor circuits are arranged on the semiconductor wafer in such a way that a frame remains on the semiconductor wafer. This frame extends to all the semiconductor circuits and surrounds each semiconductor circuit individually. Contact connections are formed on each semiconductor circuit. The contact connections are uncovered on the semiconductor wafer. Interconnects short-circuit the contact connections of a first semiconductor circuit with contact connections of at least one further semiconductor circuit. An electrical functional test can be carried out so that contact elements of a test device are placed onto the contact connections of the first semiconductor circuit, and in which the further semiconductor circuit is electrically driven via the contact elements of the test device, the contact connections of the first semiconductor circuit and the interconnects.

In this method, the interconnects between the contact connections of the first and the further semiconductor circuit are used, during an electrical functional test, to send test signals from the test device to the further semiconductor circuit and in the opposite direction. An electrical functional test is usually performed by placing a test device having a multiplicity of contact elements such as test needles, for example, onto the contact connections of the semiconductor circuits to be tested. In this position of the test device, a plurality of semiconductor circuits are tested.

During a conventional functional test, contact elements of the test device make contact with the contact connections of each semiconductor circuit to be tested. In this case, the contact elements of the test device are placed directly onto the contact connections of the semiconductor circuit to be tested. In the method according to embodiments of the invention, by contrast, the contact elements of the test device are placed onto contact connections of a first semiconductor circuit and used for testing a further semiconductor circuit, the contact connections of which are short-circuited with the contact connections of the first semiconductor circuit by the interconnects. In this case, the electrical connection between the test device and the further semiconductor circuit leads via the contact elements of the test device, the contact connections of the first semiconductor circuit and the interconnects to the contact connections of the further semiconductor circuit.

Consequently, the further semiconductor circuit can be tested with the aid of test needles that are placed onto the first semiconductor circuit instead of onto the further semiconductor circuit. This reduces the number of contact elements that are required in a specific position of the test device on the semiconductor wafer for testing a predetermined number of semiconductor circuits. In particular, there is no need for any additional test needles for testing the further semiconductor circuit, the contact connections of which are short-circuited with those of the first semiconductor circuit. The mechanical loading of the semiconductor wafer upon the emplacement of the test device is reduced by virtue of the smaller number of contact elements of the test device. In particular, there arises hardly any mechanical loading of the further semiconductor circuit on account of emplaced test needles. The risk of damage to components or component connections of semiconductor circuits is thereby reduced. Moreover, the construction of the test device is simplified. This in turn lowers the costs for producing the test device for the wafer level test.

The semiconductor wafer can be singulated in such a way that a multiplicity of semiconductor products each having two integrated semiconductor circuits that are monolithically connected to one another is produced.

As an alternative to this, the semiconductor wafer may also be singulated in such a way that a frame region of the frame that is arranged between the first semiconductor circuit and the further semiconductor circuit is destroyed and the interconnects between the first semiconductor circuit and the further semiconductor circuit are severed. The semiconductor wafer can be singulated into semiconductor chips each having only a single semiconductor circuit. These semiconductor chips can subsequently be housed individually. The singulated semiconductor chips can subsequently be provided individually with a housing. The ends of the interconnects that remain on the semiconductor chips can be left on the semiconductor chips.

The frame is preferably a sawing frame.

### BRIEF DESCRIPTION OF THE DRAWINGS

The invention is described below with reference to FIGS. 1 to 16, in which:

FIG. 1 shows a plan view of a semiconductor product according to the invention;

FIG. 2 shows a cross-sectional view of a semiconductor product according to the invention;

FIG. 3 shows a plan view of a semiconductor product according to the invention in accordance with a first embodiment;

FIG. 4 shows a development of the embodiment in accordance with FIG. 3;

FIG. 5 shows a plan view of a semiconductor product according to the invention in accordance with a second embodiment;

FIG. 6 shows a development of the embodiment in accordance with FIG. 5;

FIG. 7 shows a semiconductor product according to the invention with more than two integrated semiconductor circuits;

FIG. 8 shows a schematic illustration of the arrangement of housing-internal bonding connections of the semiconductor product from FIG. 7;

FIGS. 9 to 14 show a schematic sequence of a first method according to the invention, by means of which a semiconductor product according to the invention is produced;

FIG. 15 shows a method step of a second method according to the invention, by means of which at least one semiconductor circuit is tested; and

FIG. 16 shows a method step for the singulation of a semiconductor wafer.

The following list of reference symbols can be used in conjunction with the figures:
1 First semiconductor circuit
2, 3, 4 Further semiconductor circuit
5 Frame region
6 Test device
7 Contact element
9 Semiconductor substrate
10 Semiconductor product
11, 11a, . . . , 11e Contact connection of the first semiconductor circuit
12, 12a, . . . , 12e Interconnect
13 Control line
14 Address line
15 Clock signal line x, y Directions
16, 21, 26 Contact connection of a further semiconductor circuit
18 Insulation
19 External connection
20 Housing
25 Semiconductor circuit
29 Semiconductor wafer
35 Frame
B Bonding connection
b Width of the frame region
CS, CS0, CS1 Circuit select line
DQ, DQ0, . . . , DQ3 Data line
x, y Directions

### DETAILED DESCRIPTION OF ILLUSTRATIVE EMBODIMENTS

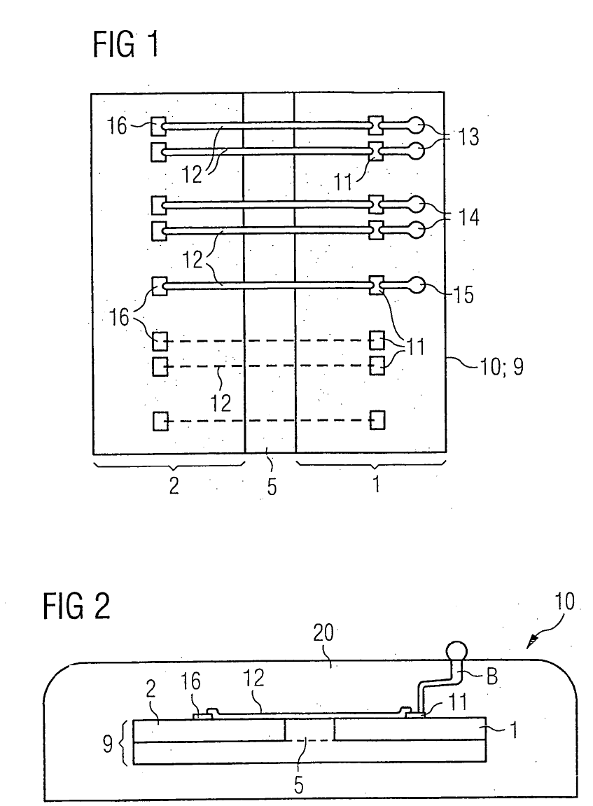

FIG. 1 shows a plan view of a semiconductor product 10 according to embodiments of the invention, which is formed on a chip, i.e., a portion of a semiconductor substrate 9. The chip has been removed from surrounding regions of a sawing frame by singulation of a semiconductor wafer. According to embodiments of the invention, the singulated semiconductor chip has a first integrated semiconductor circuit 1 and also at least one further integrated semiconductor circuit 2. A frame region 5 is arranged between the first and the further semiconductor circuit. The semiconductor circuits 1, 2 are monolithically connected to one another since the frame region 5 was not destroyed during the singulation of a semiconductor wafer.

The first semiconductor circuit 1 and the further semiconductor circuit 2 have contact connections 11, 16, which are preferably formed as bonding contact pads, i.e., as bond pads. Interconnects 12 run between the contact connections 11 of the first semiconductor circuit 1 and the contact connections 16 of the further semiconductor circuit 2, and in each case short-circuit a contact connection 11 of the first semiconductor circuit 1 with a contact connection 16 of the further semiconductor conductor 2. The interconnects 12 cross the frame region 5 and serve for connecting the first semiconductor circuit and the further semiconductor circuits in parallel.

For operating the product 10 according to embodiments of the invention, circuit-internal, integrated control lines, address lines, clock signal lines, data lines and chip select and other lines of the first and the further semiconductor circuits 1, 2 are driven by external control, address, clock signal, data and chip select and other lines via the contact connections 11, 16. The external lines are formed in the form of bonding connections in sections in the region of a housing surrounding the semiconductor product according to embodiments of the invention.

FIG. 2 shows a semiconductor product 10 according to embodiments of the invention with a housing 20, which is merely illustrated schematically and is representative of all conventional types of housing such as, for example, TSOP housings or BGA housings. The course of housing-internal bonding connects B that are used to drive the contact connections 11, 16 of the semiconductor circuits 1, 2 of the semiconductor substrate 9 is, therefore, only illustrated schematically. What is essential, however, is that the bonding connections B have to be connected to the contact connections 11 only in the region of the first semiconductor circuit 1. A direct connection to the contact connections 16 of the further semiconductor circuit 2 by means of dedicated bonding connections extending to an outer side of the housing 20 is not necessary, owing to the interconnects 12 provided according to embodiments of the invention, since the contact connections 16 of the further semiconductor circuit 2 are connected in parallel with the contact connections 11 of the first semiconductor circuit by the interconnects 12. Therefore, the semiconductor product 10 can be connected at the outer side of the housing like a conventional semiconductor product having only one semiconductor circuit and be mounted on a memory module, for instance.

These external leads B of FIG. 2 are illustrated individually in FIG. 1. In particular, control lines 13, address lines 14 and also a clock signal line 15 are illustrated, which are in each case led only to contact connections 11 of the first semiconductor circuit.

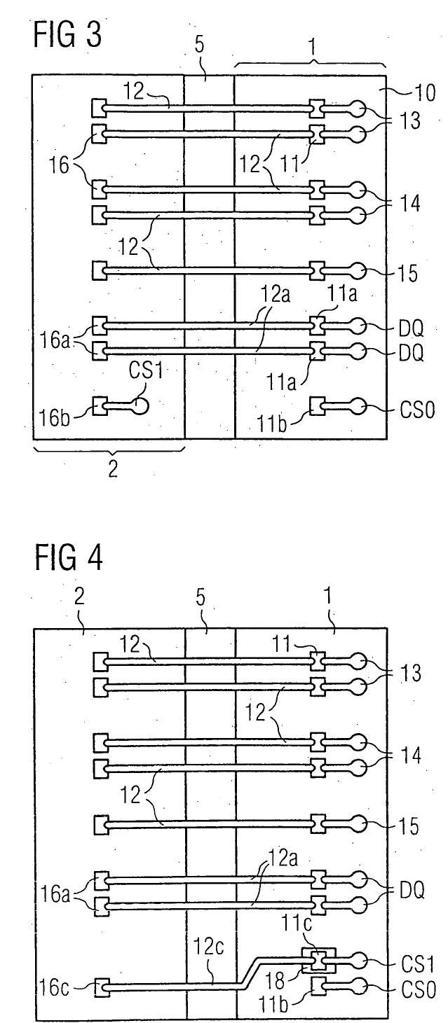

FIG. 3 shows further connecting lines, namely data lines DQ, which are connected to further contact connections 11a of the first semiconductor circuit 1. By means of the interconnects 12a, the signals of the data lines are also forwarded to contact connections 16a of the further semiconductor circuit 2. Consequently, both semiconductor circuits receive the same items of information.

The embodiment of FIG. 3 furthermore illustrates circuit select lines, namely chip select lines CS0 and CS1, which serve for activating or deactivating a respective one of the semiconductor circuits 1, 2 of the product 10. The line CS0 is connected only to a contact connection 11b of the first semiconductor circuit 1 and the line CS1 is connected only to a contact connection 16b of the further semiconductor circuit 2. As a result, the first semiconductor circuit or the further semiconductor circuit can optionally be activated. Equally, both semiconductor circuits can be activated simultaneously. By virtue of the activation of only one of the two semiconductor circuits 1, 2, both semiconductor circuits can be operated independently of one another. In comparison with a conventional semiconductor product having only a single semiconductor circuit, the semiconductor product 10 according to embodiments of the invention requires only a single additional connecting line CS1. This connecting line is connected to the contact connection 16b of the further semiconductor circuit 2. All the remaining connecting lines 13, 14, 15, DQ, CS0 are connected to contact connections 11, 11a, 11b of the first semiconductor circuit.

FIG. 4 shows a development of the embodiment in accordance with FIG. 3, in which the connecting line CS1 is connected to a contact connection 11c arranged on the first semiconductor circuit 1. However, the contact connection is electrically insulated from the first semiconductor circuit by an insulation 18 and conductively connected to a contact connection 16c of the further semiconductor circuit by an interconnect 12c that crosses the frame region 5. The development of FIG. 4 has the advantage that now all of the connecting lines including the circuit select line CS1 for the further semiconductor circuit 2 can be connected to contact connections in the region of the first semiconductor circuit. The contact connections, preferably bond pads, are usually lined up in a central region of each semiconductor circuit. The development of FIG. 4, therefore, enables space-saving contact-making through an outer housing and also contact-making that can be carried out in a simple manner during an electrical functional test during which, on the as yet unsingulated semiconductor wafer (wafer level test), compact test heads with test needles are placed onto a single integrated semiconductor circuit.

The semiconductor products according to embodiments of the invention in FIGS. 3 and 4 in each case replace pairs of conventional semiconductor products which, in order to achieve a switching capacity of identical magnitude where the product basic area remains the same, would have to be connected in pairs in each case to connecting lines of a common housing. In comparison with such “stacked devices,” the semiconductor product according to embodiments of the invention can be mounted more easily since contact is made with only a single monolithic portion of the semiconductor substrate.

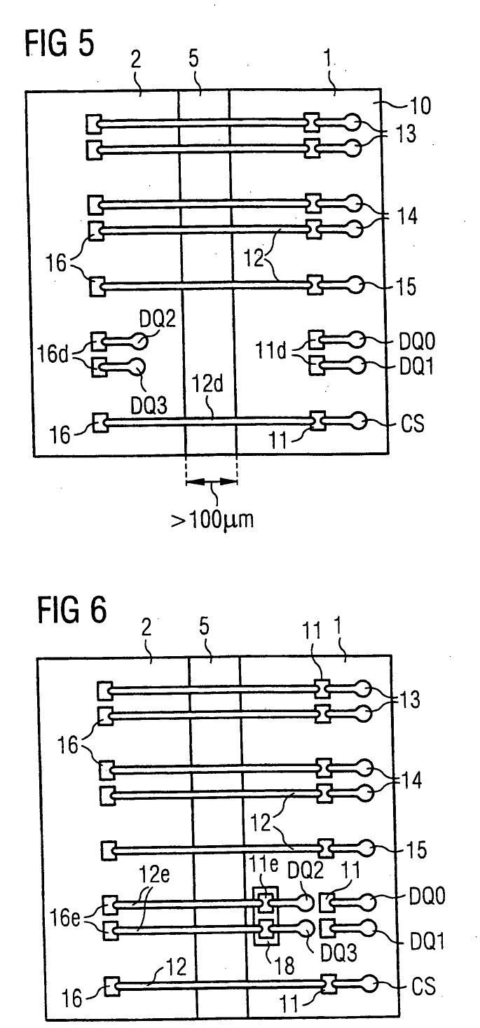

FIG. 5 shows an alternative embodiment to FIG. 3 of a semiconductor product 10 according to embodiments of the invention. In accordance with FIG. 5, only a single circuit select line CS is provided for both semiconductor circuits 1, 2, which circuit select line is directly connected to a contact connection 11 of the first semiconductor circuit 1 and is electrically connected with the aid of an interconnect 12d to a corresponding contact connection 16 of the further semiconductor circuit. The first semiconductor circuit and the further semiconductor circuit in each case have dedicated data lines that are only connected to contact connections of the respective semiconductor circuit. Thus, contact connections 11d—provided for data exchange—of the first semiconductor circuit 1 are connected to data lines DQ0 and DQ1 and contact connections 16d of the further semiconductor circuit 2 are connected to data lines DQ2 and DQ3. In each case, the two data lines DQ0, DQ1 and DQ2, DQ3 illustrated for the first semiconductor circuit and the further semiconductor circuit 1, 2, respectively, are representative of a plurality of, for example, 4, 8, 16 or 32 data lines, which are parallel to one another and are used to forward data of the respective semiconductor circuit 1, 2 that are to be stored or read out. The parallelism of the data lines, i.e., the bus width, may be chosen as desired. It is doubled, however, in the case of the semiconductor product according to embodiments of the invention with two monolithically connected semiconductor circuits 1, 2 without having to alter the integrated semiconductor circuits 1, 2 themselves. There is just as little need for this purpose for a superordinate electronic unit, for example a memory module, to be provided with a doubled bus width. A data exchange that is twice as fast is thus achieved without having to alter the layout of the integrated circuits or an electronic printed circuit board of a memory module.

If, in FIG. 5, the first semiconductor circuit 1 and also the further semiconductor circuit 2 are activated with the aid of the chip select line CS, then data can be written simultaneously to both semiconductor circuits 1, 2 via the respective data lines DQ0, DQ1, DQ2, DQ3. By virtue of all the contact connections 11, 16 of the two semiconductor circuits being connected in parallel, with the exception of the contact connections 11d, 16d for the data lines, a memory product having double the number of data lines is provided. Thus, a semiconductor product having a bus width of 16 data lines can be formed from two integrated semiconductor circuits operated with a bus width of 8 data lines. For special applications, for instance the storage of graphics, two integrated circuits that are in each case operated with a bus width of 16 data lines can be used, with the aid of the memory product according to embodiments of the invention, like a single product having a bus width of 32 parallel data lines.

FIG. 6 shows a development of the embodiment in accordance with FIG. 5, in which the data lines DQ2, DQ3 used to drive the further semiconductor circuit 2 are arranged in the region of the first semiconductor circuit 1. For this purpose, additional contact connections 11e are provided on the first semiconductor circuit 1, which contact connections are electrically insulated from the first semiconductor circuit 1 by an insulation 18. The contact connections 11e are short-circuited with contact connections 16e of the further semiconductor circuit by interconnects 12e. The additional contact connections 11e may also be arranged in a line with the remaining contact connections 11 of the first semiconductor circuit 1 in order to facilitate the connection of external bonding connections leading to a housing, or the emplacement of a test head.

The embodiments of FIGS. 5 and 6 furthermore have the advantage that, in the case of a failure of the first semiconductor circuit 1 or the further semiconductor circuit 2, an increased protection against a total failure of a superordinate electronic unit is achieved. If the semiconductor product according to embodiments of the invention is incorporated for example into a memory module that still continues to be operated in the event of a failure of 8 circuit-internal data lines of the first semiconductor circuit 1, then a total failure of the memory module is prevented by the semiconductor product according to embodiments of the invention. This is because the further semiconductor circuit 2, which is driven by the same circuit select line CS as the first semiconductor circuit 1, represents a product-internal redundancy of the memory product according to embodiments of the invention since it continues to operate in parallel even when the first semiconductor circuit 1 has failed. The redundancy of mutually independent circuits that are able to operate in parallel with one another, which redundancy is required at the level of the superordinate unit, for instance the memory module, is thereby reduced. As a result, it is possible to produce memory modules or other superordinate electronic units with a reduced outlay on circuitry without increasing the probability of failure or decreasing the “chip kill” resistance.

All of the embodiments described above afford the advantage that the number of contact connections required, for instance the number of contact pins of a TSOP housing or connections of a BGA housing, is significantly reduced. Their number can be virtually halved. As a result, a structurally superordinate unit such as a memory module, for instance, can also be configured more compactly.

FIG. 7 shows an embodiment of a semiconductor product 10 according to embodiments of the invention having more than two semiconductor circuits, namely four semiconductor circuits 1, 2, 3, 4. The contact connections 11, 16, 21, 26 of the four semiconductor circuits are in each case short-circuited with one another in groups by interconnects, each interconnect 12 short-circuiting a contact connection 11 of the first semiconductor circuit with in each case a contact connection 16 of the second semiconductor circuit 2, a contact connection 21 of the third semiconductor circuit 3 and a contact connection 26 of the fourth semiconductor circuit 4. A frame region 5 is arranged between the first semiconductor circuit and the second semiconductor circuit, and likewise between the second and the third semiconductor circuit and also between the third and the fourth semiconductor circuit. In the embodiment in accordance with FIG. 7, all four semiconductor circuits are arranged in a line next to one another. Therefore, the interconnects can be formed such that they are unbranched and rectilinear.

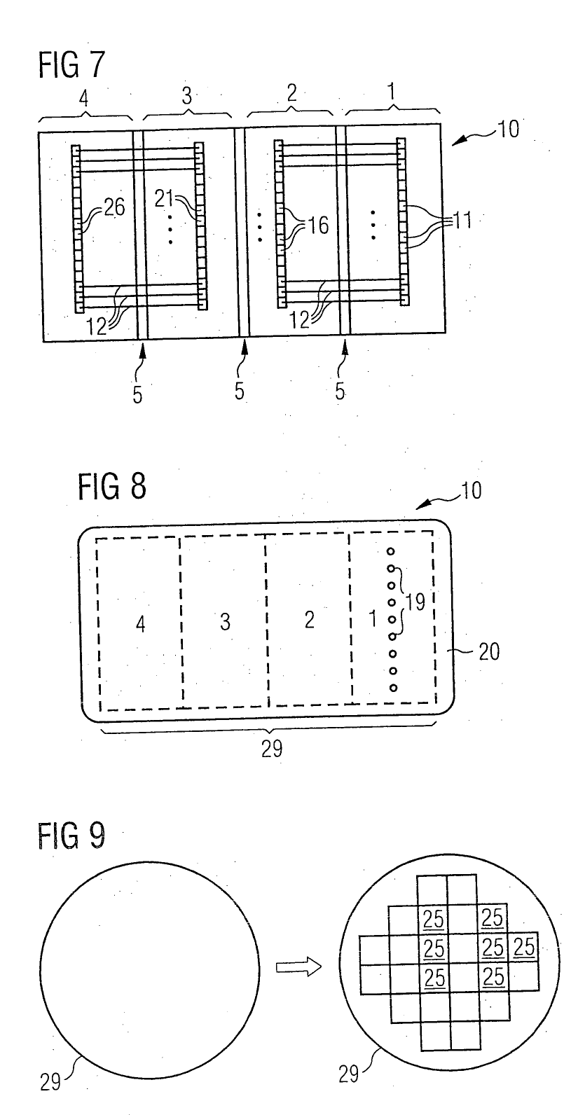

FIG. 8 shows a schematic plan view of a semiconductor product in accordance with FIG. 7 with an additional housing 20 surrounding the four semiconductor circuits 1, 2, 3 and 4. External connections 19 are illustrated in the region of the first semiconductor circuit 1, and are connected, in the interior of the housing, to contact connections 11 arranged in the region of the first semiconductor circuit 1. Bonding connections, inter alia, are used for this purpose. Although the semiconductor product in accordance with FIGS. 7 and 8 has four integrated semiconductor circuits, electrical connections between the housing 20 and the monolithic portion of the semiconductor substrate 9 are required only in the region of a single semiconductor circuit 1. The product-internal connection in parallel is effected, as illustrated in FIG. 7, with the aid of the interconnects 12.

FIGS. 9 to 14 show a first method according to embodiments of the invention, by means of which a semiconductor product according to embodiments of the invention with a plurality of semiconductor circuits that are monolithically connected to one another is produced. In accordance with FIG. 9, a semiconductor wafer 29 is provided. A multiplicity of integrated semiconductor circuits 25, which are preferably identical semiconductor circuits, are fabricated thereon.

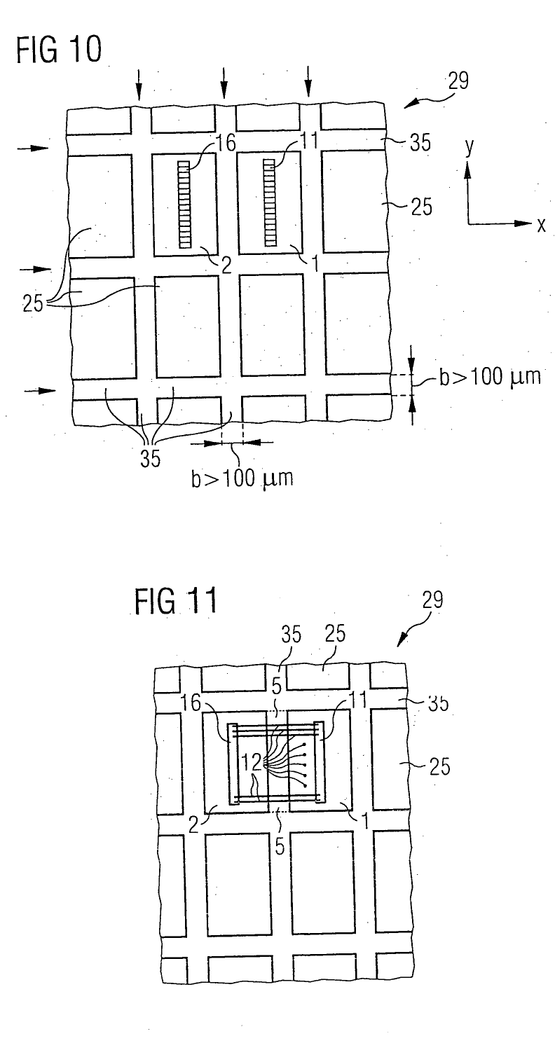

FIG. 10 shows an enlarged detail view of the semiconductor wafer 29 provided with the integrated semiconductor circuits 25. As illustrated on the basis of a first semiconductor circuit 1 and a second semiconductor circuit 2, each semiconductor circuit 25 has a plurality of contact connections 11 and 16, respectively, which are preferably lined up in the center of the respective semiconductor circuit. They contain contact connections for control lines, address lines, data lines and also for a clock signal line and a chip select line. Running between the semiconductor circuits 25 is the sawing frame 35 (kerf), which surrounds each semiconductor circuit 25 individually in each case and spatially separates it from the respective nearest adjacent circuits. In the region between respectively adjacent semiconductor circuits 25, the sawing frame 35 has a width b of at least 100 μm, preferably of 200 to 300 or up to 400 μm. In this region, the frame 35 is conventionally removed during a singulation of a semiconductor wafer or at least severed such that exclusively semiconductor chips having only a single integrated semiconductor circuit in each case are produced. For this purpose, the sawing frame 35 is sawn through along the direction of all the arrows pointing in the directions x or y in FIG. 10 and the sawing frame 35 is completely destroyed.

FIG. 11 shows a detail view of a semiconductor wafer 29, on which interconnects 12 are formed after the fabrication of the individual semiconductor circuits 1, 2. The interconnects in each case connect a contact connection 11 of a first semiconductor circuit 1 to a contact connection 16 of a further semiconductor circuit 2. In this case, the interconnects 12 cross a frame region 5 of the sawing frame 35.

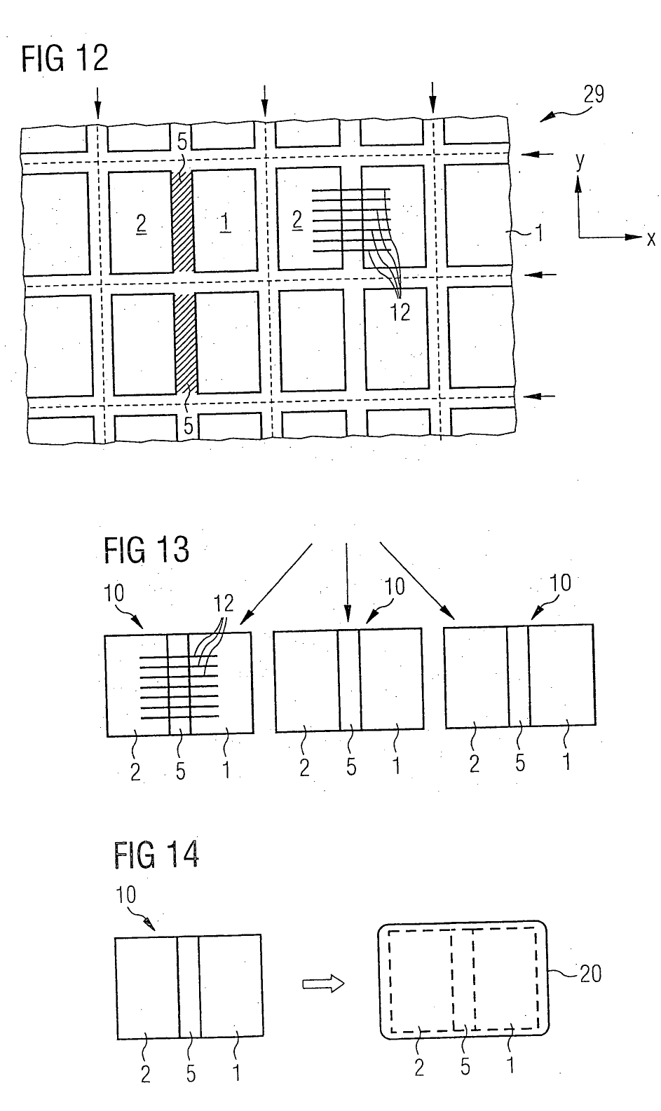

In accordance with FIG. 12, during the singulation of the semiconductor wafer 29, the integrated semiconductor circuits 1, 2 of which are short-circuited in pairs by interconnects 12, a frame region 5 arranged between two semiconductor circuits 1, 2 is in each case preserved. This is achieved by virtue of the fact that, in direction y, the semiconductor wafer 29 is sawn only at a distance of in each case two integrated semiconductor circuits, as illustrated using the vertical arrows in FIG. 9. In direction x, by contrast, the semiconductor wafer is sawn at a distance of in each case only one semiconductor circuit, as illustrated using the horizontal arrows in FIG. 12.

In accordance with FIG. 13, this type of singulation gives rise to semiconductor products 10 which, in each case, have a first integrated semiconductor circuit 1, a second semiconductor circuit 2 and also a frame region 5 situated in between. Each memory product 10 has interconnects 12 that cross the residual frame region 5 and short-circuit contact connections of the first semiconductor circuits with contact connections of the second semiconductor circuit. All of the semiconductor circuits of a semiconductor product are connected in parallel by the interconnects that are produced prior to singulation.

Finally, in accordance with FIG. 14, the semiconductor product 10 according to embodiments of the invention is housed with a housing 20.

By virtue of the invention's further use of frame regions of the sawing frame (kerf) for the monolithic connection of a plurality of semiconductor circuits of a semiconductor chip and for the arrangement of interconnects that short-circuit the contact connections of the semiconductor circuits of the semiconductor chip with one another, a semiconductor product having a higher storage capacity is provided. In comparison with a conventional product with the same design of the integrated circuits, the semiconductor product according to embodiments of the invention has a higher number of switching units, for example twice as high or even greater a number of memory banks that can be operated in parallel with one another.

If, during operation of the semiconductor product according to embodiments of the invention, individual integrated circuits of this product fail and can no longer be utilized, they can be permanently deactivated with the aid of an electrical fusible link. If an operating fault is ascertained as early as when carrying out the electrical functional test on the as yet unsingulated wafer, the relevant semiconductor circuit can be disconnected and rejected during singulation. As an alternative, a functional fault can be eliminated by means of redundant lines within the affected semiconductor circuits. In this case, in addition to electrical fusible links, laser fuses may also be provided and severed as required.

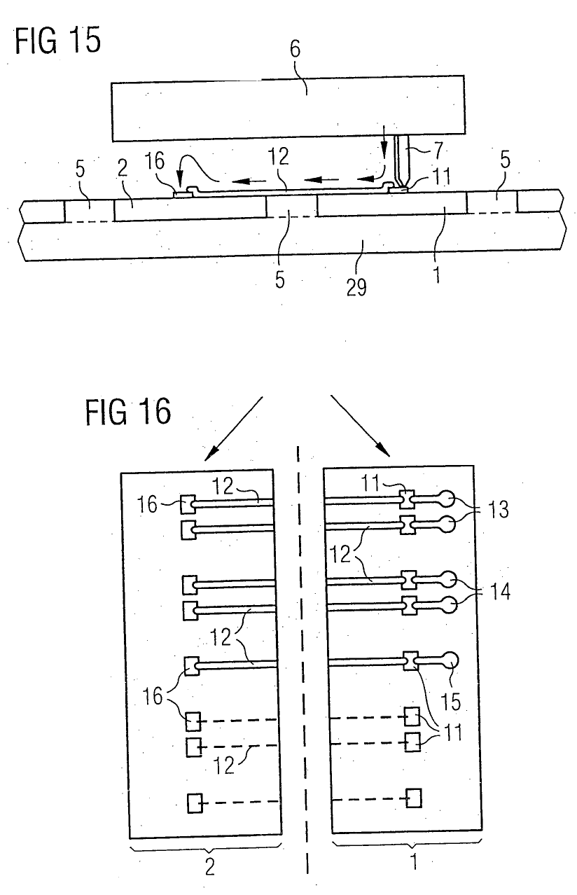

In a second method according to embodiments of the invention, the interconnects 12, which connect the contact connections 11 of the first semiconductor circuit 1 to the contact connections 16 of the further semiconductor circuit 2, are used for carrying out an electrical functional test. The second method begins like the first method according to embodiments of the invention with the method steps of providing a semiconductor wafer, fabricating the integrated semiconductor circuits on the semiconductor wafer and forming the interconnects 12, as illustrated in FIGS. 9 to 11. In the second method according to embodiments of the invention, an electrical functional test is then carried out. For this purpose, as illustrated in FIG. 15, a test device 6 having a multiplicity of contact elements 7, for example test needles, is placed onto the contact connections 11 of the first semiconductor circuit 1. The first semiconductor circuit 1 can be electrically driven and tested via the contact elements 7 and the contact connections 11. With the same contact elements 7 that are placed onto the contact connections 11 of the first semiconductor circuit 1, however, it is also possible to test the further semiconductor circuit 2. Additional contact elements of the test device 6 for testing the further semiconductor circuit 2 can be omitted even though the position of the test device 6 and of its contact elements 7 is unchanged. According to embodiments of the invention, the contact elements 7 of the test device 6 that are placed onto the contact connections 11 of the first semiconductor circuit 1 are used for electrically driving the further semiconductor circuit 2. The electrical connection between the test device 6 and the further semiconductor circuit 2 leads via the contact elements 7 of the test device 6, the contact connections 11 of the first semiconductor circuit 1, the interconnects 12 and finally via the contact connections 16 of the further semiconductor circuit 2, as is indicated by arrows in FIG. 15. Obviating contact elements 7 of the test device 6 for the testing of the further semiconductor circuit 2 reduces the mechanical loading of the semiconductor wafer 29 that arises upon the emplacement of the test device 6 (probe card). As a result, component structures or component connections within the semiconductor circuits are not damaged as easily. Moreover, the construction of the test device 6 is simplified since, for simultaneously making electrical contact with a specific number of semiconductor circuits, only a smaller number of contact elements 7 of the test device 6 are required. Consequently, the test device 6 can also be produced more cost-effectively, whereby the production costs of semiconductor chips are also lowered indirectly.

After an electrical functional test has been carried out, the semiconductor wafer 29 may be singulated. The singulation may once again be effected as illustrated in FIGS. 12 and 13. Semiconductor chips each having two semiconductor circuits that are monolithically connected to one another are produced in this case.

As an alternative, the semiconductor wafer 29 may be singulated in such a way that a frame region located between the first semiconductor circuit 1 and the further semiconductor circuit 2 is destroyed. In this case, as illustrated in FIG. 16, the interconnects 12 are severed. The region in which the sawing frame has been removed between the first semiconductor circuit 1 and the further semiconductor circuit 2 is indicated by a dashed line in FIG. 16, the dashed line simultaneously corresponding to the cutting line or sawing line when severing the interconnects 12. This type of singulation gives rise to semiconductor chips each having only a single semiconductor circuit 1, 2. They may be housed individually as in a conventional manner. The residues of the interconnects 12 that have remained on the semiconductor circuits need not be removed, but rather can remain on the semiconductor circuits 1, 2. An additional fabrication step is thereby obviated.

1. A semiconductor product comprising:
a first semiconductor circuit and at least one further integrated semiconductor circuit arranged together on a semiconductor substrate, the first semiconductor circuit and the at least one further semiconductor circuit being separated from one another by a frame region, the first semiconductor circuit and the at least one further semiconductor circuit each including contact connections; and
interconnects that cross the frame region, each interconnect short-circuiting a contact connection of the first semiconductor circuit with a contact connection of the at least one further semiconductor circuit.

2. The semiconductor product as claimed in claim 1, wherein the semiconductor product includes control lines and address lines that are connected directly to the contact connections of the first semiconductor circuit and that are short-circuited with contact connections of the at least one further semiconductor circuit by the interconnects.

3. The semiconductor product as claimed in claim 1, wherein the semiconductor product further includes data lines and a circuit select line, the circuit select line to carry a signal that enables a semiconductor circuit to be driven to be activated.

4. The semiconductor product as claimed in claim 3, wherein the data lines are connected directly to contact connections of the first semiconductor circuit and are short-circuited with contact connections of the at least one further semiconductor circuit by the interconnects.

5. The semiconductor product as claimed in claim 4, wherein a dedicated circuit select line is provided for each semiconductor circuit of the semiconductor product, said dedicated circuit select line being conductively connected only to the respective semiconductor circuit.

6. The semiconductor product as claimed in claim 5, wherein the at least one further semiconductor circuit is assigned a circuit select line that is connected directly to a contact connection that is arranged on the first semiconductor circuit, wherein the at least one further semiconductor circuit is electrically insulated from the first semiconductor circuit and wherein the at least one further semiconductor circuit is short-circuited with a contact connection of the at least one further semiconductor circuit by an interconnect.

7. The semiconductor product as claimed in claim 3, wherein the circuit select line is connected directly to a contact connection of the first semiconductor circuit and is short-circuited with a contact connection of the at least one further semiconductor circuit by an interconnect, wherein dedicated data lines are provided for each semiconductor circuit of the semiconductor product, said dedicated data lines being conductively connected only to the respective semiconductor circuit.

8. The semiconductor product as claimed in claim 7, wherein the at least one further semiconductor circuit is assigned data lines that are connected directly to contact connections that are arranged on the first semiconductor circuit, wherein the at least one further semiconductor circuit is electrically insulated from the first semiconductor circuit and wherein the at least one further semiconductor circuit is short-circuited with contact connections of the at least one further semiconductor circuit by interconnects.

9. The semiconductor product as claimed in claim 1, wherein the semiconductor product includes a clock signal line that is connected directly to a contact connection of the first semiconductor circuit and that is short-circuited with a contact connection of the at least one further semiconductor circuit by an interconnect.

10. The semiconductor product as claimed in claim 1, wherein the frame region comprises a region of a sawing frame of a semiconductor wafer that has been preserved between the first and the at least one further semiconductor circuit.

11. The semiconductor product as claimed in claim 1, wherein the first semiconductor circuit and the at least one further semiconductor circuit are arranged at a distance from one another of more than 100 micrometers.

12. The semiconductor product as claimed in claim 1, wherein the contact connections comprise bonding contact pads.

13. The semiconductor product as claimed in claim 12, wherein the semiconductor product further includes a housing and wherein lines connected to the contact connections of the first semiconductor circuit are formed as bonding connections in sections in the housing.

14. The semiconductor product as claimed in claim 1, wherein the semiconductor product has precisely two semiconductor circuits, the contact connections of which are short-circuited with one another in each case in pairs by the interconnects.

15. The semiconductor product as claimed in claim 1, wherein the at least one further semiconductor circuit comprises a plurality of semiconductor circuits, the first semiconductor circuit and the further semiconductor circuits being separated from one another by the frame region on the semiconductor substrate and wherein the contact connections are in each case short-circuited with one another by interconnects.

16. The semiconductor product as claimed in claim 15, wherein the first semiconductor circuit and all the further semiconductor circuits, the contact connections of which are short-circuited with the contact connections of the first semiconductor circuit by the interconnects, are structurally identical semiconductor circuits.

17. The semiconductor product as claimed in claim 1, wherein the first semiconductor circuit and the at least one further semiconductor circuit comprise memory circuits.

18. The semiconductor product as claimed in claim 17, wherein the first semiconductor circuit and the at least one further semiconductor circuit comprise dynamic random access memories.

19. A method for producing a semiconductor product, the method comprising:
providing a semiconductor wafer;
fabricating a multiplicity of integrated semiconductor circuits on the semiconductor wafer, the semiconductor circuits being arranged on the semiconductor wafer in such a way that a frame remains on the semiconductor wafer, the frame extending to all the semiconductor circuits and surrounding each semiconductor circuit individually, wherein fabricating the multiplicity of integrated semiconductor circuits includes forming contact connections on each semiconductor circuit, said contact connections being uncovered on the semiconductor wafer;
forming interconnects that short-circuit the contact connections of a first semiconductor circuit with contact connections of at least one further semiconductor circuit; and
singulating the semiconductor wafer in such a way that a frame region of the frame that is arranged between the first semiconductor circuit and the further semiconductor circuit is preserved and the first semiconductor circuit and the further semiconductor circuit remain monolithically connected.

20. The method as claimed in claim 19, further comprising housing the first semiconductor circuit and the at least one further semiconductor circuit jointly in a housing.

21. The method as claimed in claim 19, wherein the frame comprises a sawing frame.

22. The method as claimed in claim 19, wherein the semiconductor wafer is singulated in such a way that a multiplicity of semiconductor products are produced, each semiconductor product including two integrated semiconductor circuits that are monolithically connected to one another.

23. A method for testing at least one semiconductor circuit, the method comprising:
providing a semiconductor wafer;
fabricating a multiplicity of integrated semiconductor circuits on the semiconductor wafer, the semiconductor circuits being arranged on the semiconductor wafer in such a way that a frame remains on the semiconductor wafer, the frame extending to all the semiconductor circuits and surrounding each semiconductor circuit individually, wherein fabricating a multiplicity of integrated semiconductor circuits including forming contact connections on each semiconductor circuit, said contact connections being uncovered on the semiconductor wafer;
forming interconnects that short-circuit the contact connections of a first semiconductor circuit with contact connections of at least one further semiconductor circuit; and
carrying out an electrical functional test such that contact elements of a test device are electrically connected to contact connections of the first semiconductor circuit, and wherein the at least one further semiconductor circuit is electrically driven via the contact elements of the test device, the contact connections of the first semiconductor circuit and the interconnects.

24. The method as claimed in claim 23, further comprising singulating the semiconductor wafer in such a way that a multiplicity of semiconductor products are produced, each semiconductor product having two integrated semiconductor circuits that are monolithically connected to one another.

25. The method as claimed in claim 23, further comprising singulating the semiconductor wafer in such a way that a frame region of the frame that is arranged between the first semiconductor circuit and the at least one further semiconductor circuit is destroyed and the interconnects between the first semiconductor circuit and the at least one further semiconductor circuit are severed.

26. The method as claimed in claim 23, wherein the frame comprises a sawing frame.
